(19) United States
(12) Patent Application Publication
(10) Pub. No.: US 2023/0420588 A1
(43) Pub. Date: Dec. 28, 2023

(54) MOLDED DECORATIVE SOLAR PANEL AND METHOD OF MANUFACTURE THEREOF

(71) Applicant: APTERA MOTORS CORP., San Diego, CA (US)

(72) Inventors: Anuj THAKKAR, San Diego, CA (US); Bradly PATCHEN, Oceanside, CA (US)

(73) Assignee: APTERA MOTORS CORP., San Diego, CA (US)

(21) Appl. No.: 18/342,228

(22) Filed: Jun. 27, 2023

Related U.S. Application Data
(60) Provisional application No. 63/356,454, filed on Jun. 28, 2022.

(51) Int. Cl. H01L 31/048

(52) U.S. Cl. CPC H01L 31/048

(57) ABSTRACT

An apparatus, system, and method is disclosed, which integrates a flexible solar module with a freestanding, molded panel assembly in a curved geometry, such as for a vehicle dashboard, using insert molding. A flexible solar module with surface texture may be integrated with a larger body panel with a seamless, flush surface and uninterrupted texture. A flexible module may be adhered to a textured cap sheet and overmolded on a back side. A smooth, flexible module may be over-molded on a front or back side, in a single molding operation. A smooth, flexible module may be overmolded on front and back sides using two molding operations. Methods of flexible and rigid module retention within the insert mold are disclosed. Methods of surface texturing are also described. Furthermore, methods of concealing the solar cells through color matching are disclosed.

### CROSS REFERENCE TO RELATED APPLICATIONS

This application is a continuation of, and claims priority to, co-pending U.S. Provisional Patent Application No. 63/356,454, filed Jun. 28, 2022, entitled, “MOLDED DECORATIVE SOLAR PANEL AND METHOD OF MANUFACTURE THEREOF”, the disclosure of which is incorporated by reference herein in its entirety.

### TECHNICAL FIELD

The present disclosure relates generally to flexible solar modules integrated with a molded panel assembly in a curved geometry, and specifically to an apparatus, system, and method for a vehicle dashboard incorporating a decorative solar module that may be curved in one direction.

### BACKGROUND

Recently the demand for mobile solar panels and non-flat geometry solar panels has sparked innovations for both polymer- and glass-based panels. Such applications value light weight, durability and low cost. However, other considerations, such as appearance and surface texture, have become important in consumer applications. Some of the most challenging requirements come from the electric vehicle industry where solar-enabled body panels have been a topic of intense research and development for three decades. Vehicle body panels typically have complex shapes and harsh environment operability and durability requirements. However, solar panels having complex geometries are challenging to manufacture for a variety of reasons, the most obvious of which is damage to or destruction of the delicate solar cells. In applications where solar modules are integrated with components that are expected to receive human contact, the look and feel of such components have a bearing on their marketability. The current disclosure addresses this need for any molded panel application, and, by way of example, uses the embodiment of an automotive dashboard application to discuss specific enabling features. Nevertheless, the present invention is not specifically limited thereto as a solar panel having a complex shape has applications in architectural, marine, aeronautical, space, and other useful applications.

Previously, solar modules have been applied to or integrated with dashboards using one of two conventional methods. In a first method, a thin, flexible solar module either incorporated into a flexible dashboard cover or as a flexible stand-alone solar module of the type commercially available, as for example, from Renogy LLC Ontario, California, is either placed or adhered to the surface of a molded dashboard as an aftermarket installation. In this case, the solar module and cells are either flat or curved in a single dimension.

In a second method, a solar module is integrated with the dashboard via injection molding. For injection molding, the solar module or individual cells remain flat while the outer facing surface of the dashboard panel may be curved. To retain a flat form, the solar module may be restricted to a flat portion of the dashboard surface, or it may be disposed on a flat subsurface, such as the back surface. Alternatively, it may be disposed on a flat intermediate surface, or an array of such surfaces, enclosed between top and bottom portions of the dashboard.

In the injection molding approach, sealing of the edge of a solar panel is made by a backside molding followed by a frontside molding so as to encapsulate the cells or module in the injected polymer thereby sealing the edges. A frontside only approach is possible but has disadvantages as a back sheet or other sealing arrangement is required to protect the module against moisture. In the frontside only approach a clear resin must be used above the solar cells and color matching is therefore not possible without an additional backsheet. Moreover, edge sealing of the solar module would also require an additional backsheet and may involve additional steps in the manufacturing process.

Similarly, a backside only injection molding approach requires retention of the solar module during the injection process, typically using a recess in the mold, resulting in a solar module that protrudes from dashboard surface, thereby exposing the panel edge. As a further consequence, the module is not produced with a suitable appearance and design for consumer applications such as, for example, a flush, uninterrupted interface between the solar module and the dashboard.

In most consumer applications surface texture and color must be controlled for visual appearance, tactile purposes and other characteristics for commercial sale and use. For example, in a dashboard application, minimizing reflection of light from the dashboard, either directly from the ambient light or by indirect reflection from the windshield, is an important characteristic for driver safety. A smooth or glossy finish typically increases reflections and can lead to significant glare for the occupants. In another example, consumer sales can depend on a desirable appearance of the dashboard with its surroundings such that the solar cells blend into the surrounding material, are faintly perceptible, indistinct, or are otherwise obscured from view. In conventional molding techniques for solar modules, surface texture and color and are generally overlooked.

What is needed is a solar-enabled panel and method of fabrication configured to include simple or complex curvature, a decorative or color-matched appearance, integral structural elements for securing the molded panel to the vehicle structure, and a seamless, robust, textured surface that can minimize reflections and withstand intense solar radiation and repeated human contact over the life of the panel. Other desirable features and characteristics will become apparent from the subsequent detailed description, the drawings, and the appended claims, when considered in view of this background.

### SUMMARY

It is an object of the present disclosure to provide an apparatus, system and method for a laminated, solar-enabled body panel for a vehicle with at least one axis of curvature that has a seamless, robust, textured surface and a decorative appearance suitable for consumer applications.

It is an object of the present disclosure to provide a system and method for producing a solar-enabled panel with the qualities of wear and impact resistance, durability, and long-term performance.

It is an object of the present disclosure to provide a molding process for integrating a flexible solar panel with a vehicle body panel at a low cost and in high volume.

### DESCRIPTION OF THE DRAWINGS

Non-limiting and non-exhaustive embodiments of the present disclosure are described with reference to the following drawings. In the drawings, like numerals describe like components throughout the several views.

For a better understanding of the present disclosure, reference will be made to the following Detailed Description, which is to be read in association with the accompanying drawings, which are incorporated in and constitute a part of this specification, show certain aspects of the subject matter disclosed herein and, together with the description, help explain some of the principles associated with the disclosed implementations, wherein:

FIG. 1A illustrates a perspective view of a curved dashboard assembly including an integrated flexible solar module without surface texture, according to an embodiment of the present invention;

FIG. 1B illustrates a perspective view of a curved panel assembly including an integrated flexible solar module with surface texture, according to an embodiment of the present invention;

FIG. 2A illustrates an exploded, perspective view of solar module layers arranged in a stack, according to an embodiment of the present invention;

FIG. 2B illustrates a perspective view of a flexible solar module that has been laminated as a flat sheet, according to an embodiment of the present invention;

FIG. 2C illustrates a perspective view of a laminated flat sheet flexible solar module with a textured surface, according to an embodiment of the present invention;

FIG. 3 illustrates a cross-sectional view of a texture imparted to the frontsheet of an integrated flexible solar module, according to an embodiment of the present invention;

FIG. 4A illustrates a section view of an insert injection mold for use in a single, backside injection molding operation wherein the module insert and mold have interlocking surface textures, according to an embodiment of the present invention;

FIG. 4B illustrates a section view of a curved panel assembly with an integrated flexible solar module encapsulated by a backside injection molding operation having a continuous, flush surface texture, according to an embodiment of the present invention;

FIG. 5A illustrates a section view of an insert injection mold for use in a single, backside injection molding operation with a flexible solar module and textured cap sub-assembly insert, according to an embodiment of the present invention;

FIG. 5B illustrates a section view of a curved panel assembly with an integrated flexible solar module encapsulated by a backside injection and having a frontside continuous, flush surface texture, according to an embodiment of the present invention;

FIG. 6A illustrates a section view of an insert injection mold for use in a single, frontside injection molding operation with a flexible solar module wherein the module is retained in a recess within the mold, according to an embodiment of the present invention;

FIG. 6B illustrates a section view of a curved panel assembly with an integrated flexible solar module encapsulated by a frontside injection operation having a continuous, flush surface texture and a secondary backsheet, according to an embodiment of the present invention;

FIG. 7A illustrates a section view of an insert injection mold for use in a single, frontside injection molding operation with a flexible solar module disposed in the recess of a pre-molded panel wherein the module/panel subassembly is retained in the mold cavity, according to an embodiment of the present invention;

FIG. 7B illustrates a section view of a curved panel assembly encapsulated by a frontside molding operation with an integrated flexible solar module having a continuous, flush surface texture, according to an embodiment of the present invention;

FIG. 8A illustrates a section view of an insert injection mold for use in a single, frontside injection molding operation with a flexible solar module disposed on a secondary backsheet having the module/backsheet subassembly retained in the mold cavity, according to an embodiment of the present invention;

FIG. 8B illustrates a section view of a curved panel assembly encapsulated by a frontside molding operation with an integrated flex s-module and secondary backsheet having a continuous, flush surface texture, according to an embodiment of the present invention;

FIG. 9A illustrates a section view of an insert injection mold for use in a double injection molding operation with a flexible solar module retained in a mold recess, according to an embodiment of the present invention;

FIG. 9B illustrates a section view of a curved sub-panel with an integrated flexible solar module wherein the module protrudes from the sub-panel formed by a backside molding operation according to the invention;

FIG. 9C illustrates a section view of an insert injection mold for use in a double injection molding operation with a curved sub-panel retained in the mold cavity according to an embodiment of the present invention;

FIG. 9D illustrates a section view of a curved panel assembly encapsulated by a frontside molding operation with an integrated flexible solar module having a continuous, flush surface texture, according to an embodiment of the present invention;

FIG. 10A illustrates a section view of an insert injection mold for use in a double injection molding operation with a flexible solar module retained in a mold recess, according to an embodiment of the present invention;

FIG. 10B illustrates a section view of a curved sub-panel formed by a frontside molding operation with an integrated flexible solar module wherein the module protrudes from the sub-panel according to the invention;

FIG. 100 illustrates a section view of an insert injection mold for use in a double injection molding operation with a curved sub-panel wherein the sub-panel is retained in the mold cavity, according to an embodiment of the present invention;

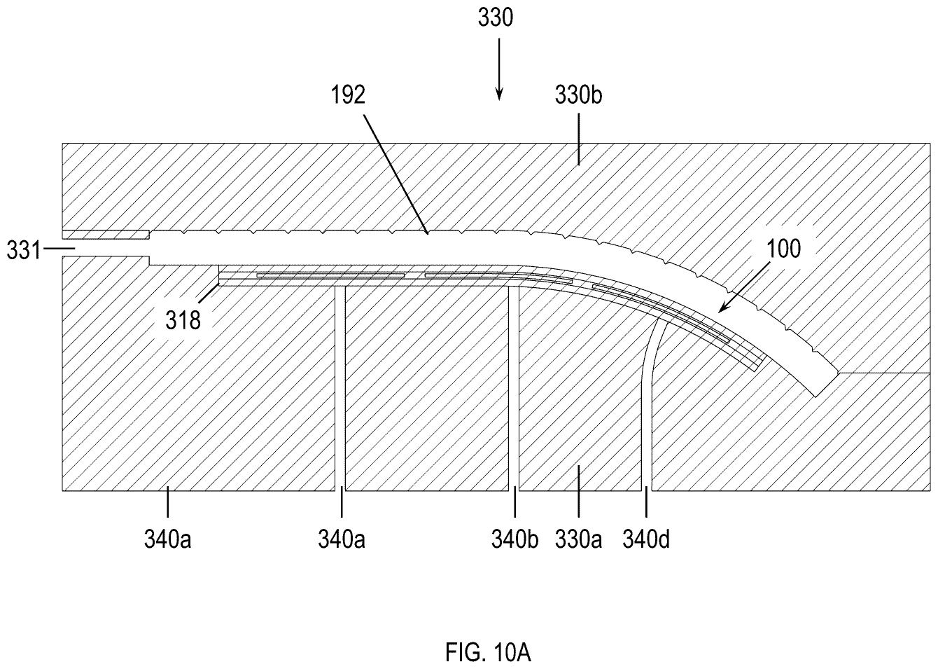

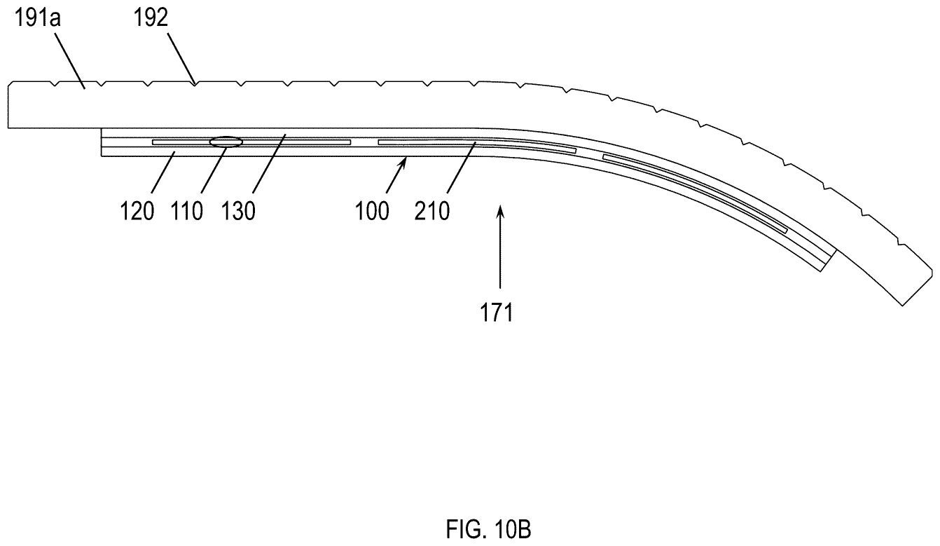

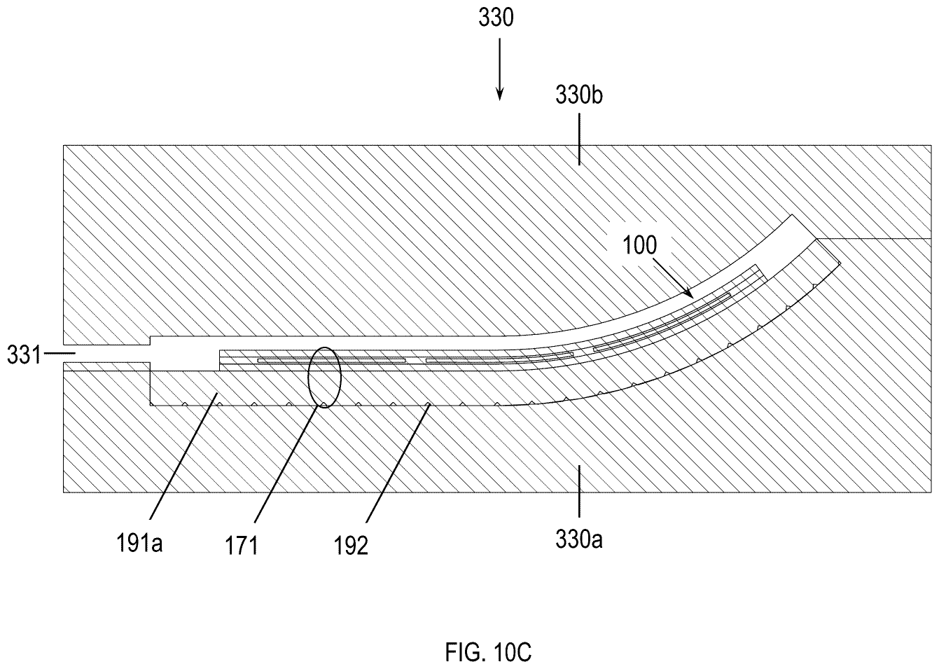

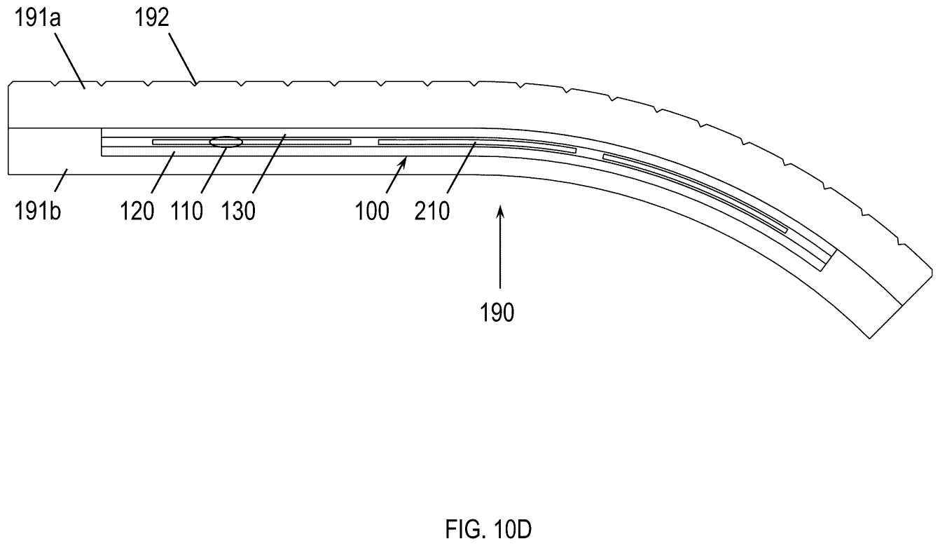

FIG. 10D illustrates a section view of a curved panel assembly encapsulated by a backside molding operation with an integrated flexible solar module having a continuous, flush surface texture, according to an embodiment of the present invention.

### DETAILED DESCRIPTION

Non-limiting embodiments of the invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention and are not to be considered as limitation thereto.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The drawings featured in the figures are provided for the purposes of illustrating some embodiments of the present disclosure, and are not to be considered as a limitation thereto. The term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

The term “integrate” or “integrated” or means that the solar panel is combined with the dashboard in such a way that it cannot be removed without significant effort and/or damaging the assembly. The term “integrate” or “integrated” may further, or alternatively, refer to a solar module and/or dashboard installed by the original equipment manufacturer (OEM), which may not be easily removed by the user and requires significant labor and/or expense for repair or replacement.

The term “panel”, “molded panel”, or “panel assembly” refers to a unitary structure fabricated from a plurality of parts such as, for example, a solar module and a support structure for a vehicle body part, that are combined in such a way that the structure cannot be disassembled without significant effort and/or damaging the assembly such as, for example, a dashboard, tailgate cover, or other body part.

The term “module”, “solar module”, or “flex s-module” means individual solar cells and/or solar arrays in a flexible laminate connected in such a way that individual solar cells and/or solar arrays cannot be removed without significant effort and/or damaging the laminated solar assembly.

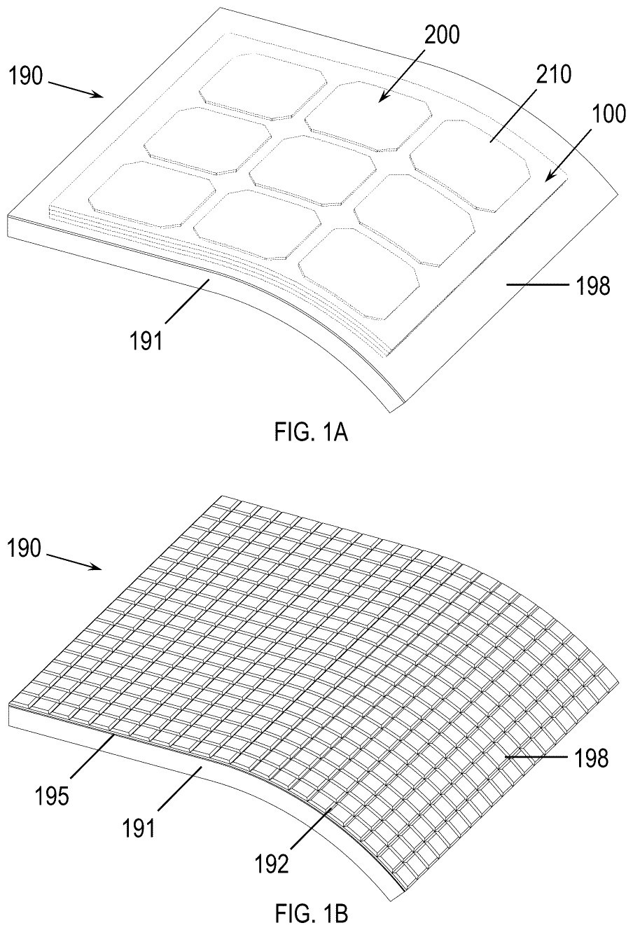

The drawings, including FIGS. 1A through 10D, may contain sizes and shapes of respective portions that are appropriately exaggerated for ease of understanding. Therefore, the comparative sizes and/or shapes displayed in the drawings should be considered non-limiting.

In a first embodiment, illustrated in FIGS. 1A and 1B, a dashboard assembly 190 comprises a flexible solar module (flex s-module) 100 with a textured surface 192 integrated with a molded panel 191. In FIG. 1A the flex s-module 100 may be flat or have simple curvature, that is, curved in one direction, such that the individual cells 210 may also be flat or curved in one direction, such as for a panel molded for the dashboard of a vehicle. The solar module 100, shown in FIG. 1A without surface texture for clarity, comprises a solar cell array 200 having electrically connected individual solar cells 210 using a plurality of interconnects (not shown). Solar cells 210 may be of the semi-flexible, interdigitated, back-contact cell type, available from multiple vendors, such as SunPower which produces the Maxeon® Gen III (3) flexible solar cell. However, other types of solar cells, such as a heterojunction, thin film, perovskite, or other type of solar cell, may also be used and the previous example is offered without limitation. Solar cells 210, as shown in FIG. 1A, may be arranged with a short axis oriented substantially parallel to the longitudinal axis of the vehicle, such that the short axis of the cell may be curved. Alternatively, solar cells 210 may be arranged with a long axis of the cell, i.e., the diagonal axis, oriented substantially parallel to the longitudinal axis of the vehicle, such that the long axis of the cell may be curved. The array 200 is surrounded by encapsulant layers and protective sheets.

Referring to FIG. 1B, a top layer of the solar-enabled body panel 190 may be textured 192 to provide a pleasing tactile perception, to reduce reflection of the light incident on the solar cells, reduce reflections from the panel into the eyes of the driver and occupants, and/or to provide a decorative appearance. A bottom layer or interface below the solar cells 210 may be colored or printed to provide an aesthetic appearance and/or to cause the cell array 200 to blend into the dashboard and/or the surrounding structures by reducing contrast thereof.

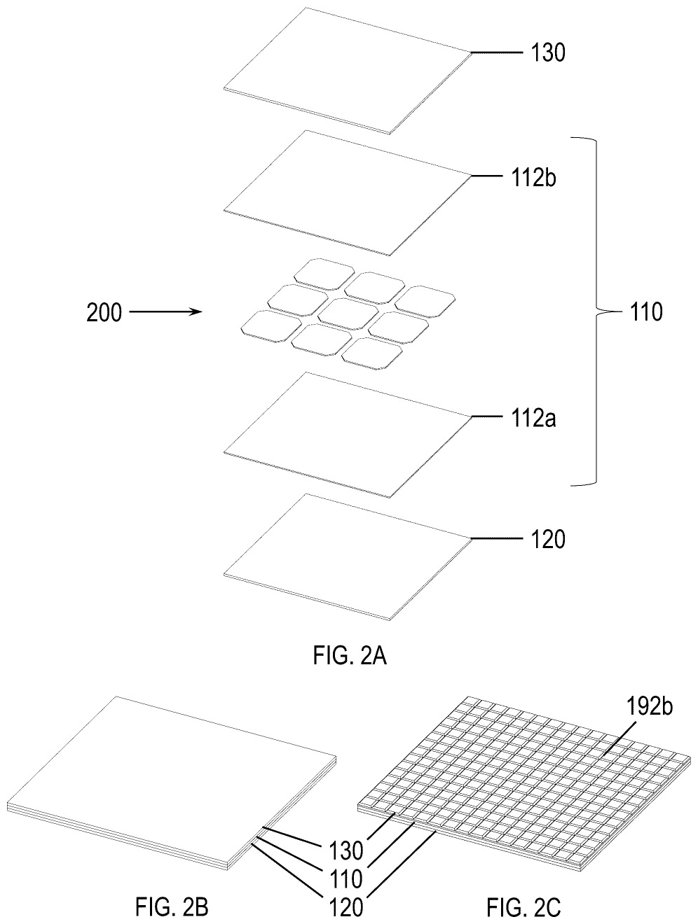

FIGS. 2A-2C illustrate features and characteristics of the flex s-module 100 and its method of manufacture. Referring to FIG. 2A, the flex s-module 100 comprises a core 110, a backsheet 120 and a frontsheet 130. The thicknesses of the layers are chosen such that the flex s-module 100 remains flexible after lamination. The backsheet 120 comprises a thin layer of a durable polymer, such tedlar polyester tedlar (TPT) or ethylene tetrafluoroethylene (ETFE). The backsheet 120 may be colored by means of dyeing of the extrudate, post-extrusion dyeing, or by spraying or printing of paint or ink on one or both surfaces. Alternatively, the backsheet 120 may not be colored at all, with color being applied in a later injection molding step.

The core 110 comprises a solar cell array 200 encapsulated in a flowable polymer 112a-b, such as polyolefin elastomers (POE) or ethylene vinyl acetate (EVA). The frontsheet 130 is the topmost layer of the laminate stack and comprises a durable polymer capable of short-range deformation (<1 mm) imparted by low force tooling, such as the film form of ETFE or polycarbonate (PC). It may be appreciated by one skilled in the art that other choices of material for the various layers may be made and the specific examples mentioned here are therefore non-limiting. The frontsheet 130 may have a textured surface 192b that matches the textured surface 192a of the molded panel 191 sealing the edges of the flex s-module 100.

FIGS. 2A-2C illustrate features and characteristics of the flex s-module 100 and its method of manufacture. In a first step, shown schematically in FIG. 2A, the solar panel layers are arranged in a stack. The stack represents the order of the layers and may be implemented as sheets, as in a flat lamination process, or as rolls, as in a roll-to-roll lamination process. The backsheet 120 is disposed at the bottom, followed by the core 110 comprising a bottom encapsulant 112a, the solar cells 210, and a top encapsulant 112b. A frontsheet 130 may be disposed on the core 100 layers. The backsheet 120 and frontsheet 130 may comprise a plurality of layers. In addition, the backsheet 130 may be colored or have a decorative design so as to improve the aesthetic quality of the dashboard once the flex s-module 100 is integrated. Color and texture are desired characteristics of a dashboard design to reduce the reflection of the solar panel in the windshield of the vehicle from the perspective of the driver and/or passenger(s). Another potential design goal is to hide the solar-enabled nature of the panel, and present a surface with a seamless, uniform color. This may be achieved by selecting resin and/or resin color for the surfaces of the molded panel 191, the flex s-module 100 and/or the backsheet 120 using a measurement of delta E (LIE), established by the International Commission on Illumination (CIE), between any two surfaces of the dashboard assembly 190. Color matching is considered good for a ΔE of less than about 2. Still another potential design goal is to differentiate the panel by not color matching and instead presenting a more decorative appearance provided by a printed design. In the latter case, printing materials and methods, including distortion printing, may be used to compensate for the curvature of the dashboard assembly, as described in International Patent Application Number PCT/US23/63600 filed Mar. 2, 2023 entitled “PROCESS FOR MAKING CURVED LAMINATED SOLAR PANEL HAVING DECORATIVE APPEARANCE USING DISTORTION PRINTING AND PANEL PRODUCED THEREBY”, which is incorporated herein by reference in its entirety.

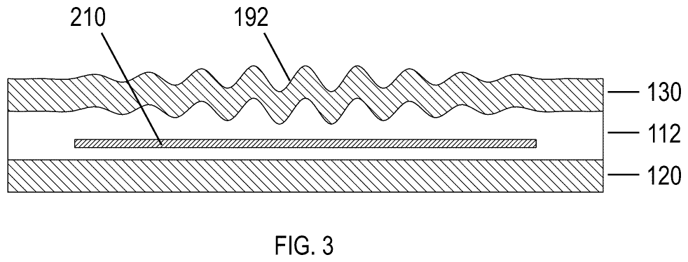

In a second step, shown in FIG. 2B, the flex s-module 100 is laminated as a flat sheet. Referring to FIG. 2C, the frontsheet 130 may be textured 192b during the lamination process by a plurality of techniques known in the art, such as, for example, textured rollers in a roll-to-roll lamination process, a textured mold in a flat lamination process, or a textured insert placed on the frontsheet in a flat lamination process. As depicted in FIG. 3, the texture 192 is imparted to the thin frontsheet 130 by one of the above-mentioned techniques and is accommodated by the flowable polymer encapsulant 112. In this way, the solar cells 210 are not stressed by the texturing process. In a third step, the flex s-module 100 may be trimmed to the appropriate dimensions. Trimming may be achieved through mechanical cutting or laser cutting.

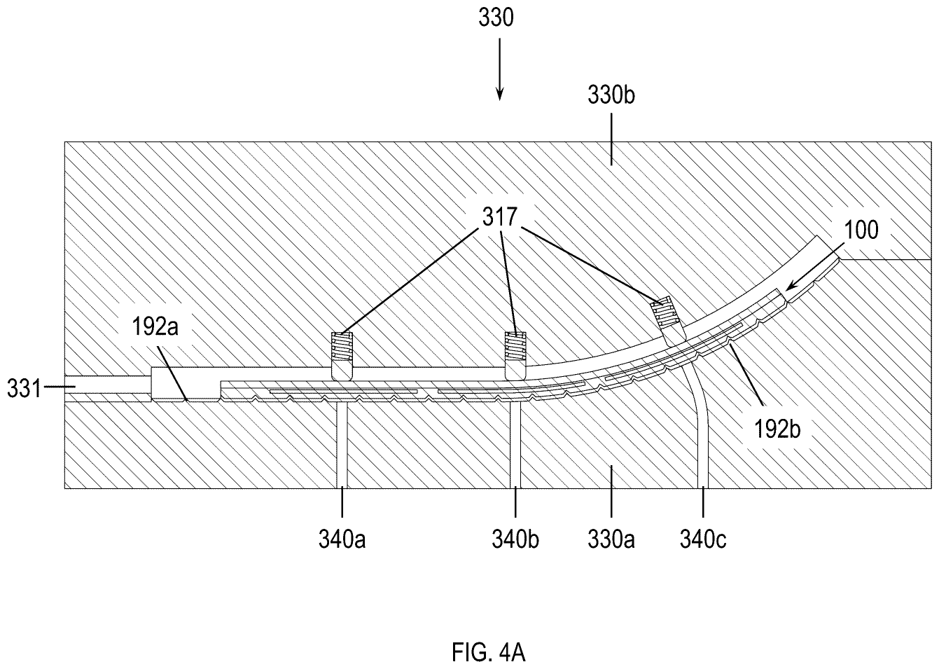

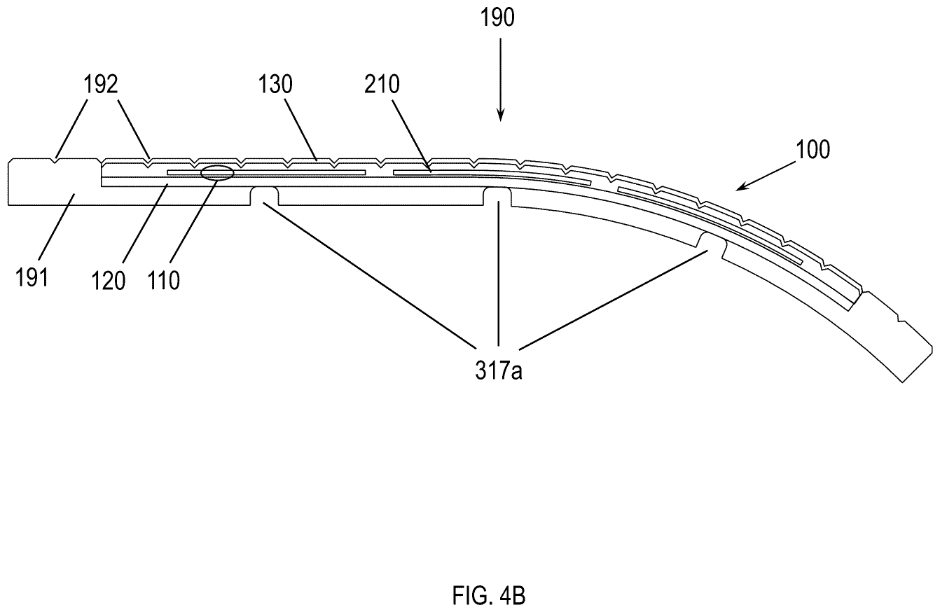

FIG. 4A illustrates a method of integrating a dashboard assembly 190 with a flex s-module 100 by insert molding. A mold 330 comprising two sides, an A-side 330a and a B-side 330b, form a cavity into which the flex s-module 100 is inserted. In this embodiment, the flex s-module 100 has a textured surface 192b matching the textured surface 192a of the A-side of the mold 330a. The textured surfaces 192a and 192b are of sufficient geometry to positively locate and/or interlock the flex s-module 100 with respect to the mold 330a. Alternatively, or in addition, a vacuum applied to holes 340a, 340b and 340c in the A-side 330a may be used to secure the flex s-module 100 in place before and during the injection process.

Alternatively, or additionally, the flex s-module 100 may be held in place by mechanical retention elements protruding from the B-side 330b, such as, for example, mold protrusions, spring loaded pins 317 or sacrificial retention elements, such as plastic, metal, or ceramic dowels. Such sacrificial retention elements would become embedded in, and therefore part of, the dashboard assembly 190. In the injection process, a polymer charge is heated, pressurized and injected into the mold cavity through the runner 331 or other inlet. The runner 331 may be located on the B-side 330b of the mold and be substantially parallel to the surface of the flex s-module 100 and mold cavity. Alternatively, the runner may be oriented substantially perpendicular to the mold cavity or any angle therebetween and may be alternately disposed in the A-side. Additional mold features, such as multiple inlets to the cavity, vents or overflow cavities, as are known in the art, may be used to achieve an even flow pattern for the plastic and facilitate a complete filling of the cavity.

FIG. 4B illustrates the dashboard assembly 190 resulting from the backside only molding operation of FIG. 4A. The injected plastic is opaque and forms a molded panel 191 that bonds to and seals the edges of the flex s-module 100. The flex s-module 100 surface comprises a lamination induced texture 192, which is confined to the core 110 and frontsheet 130 layers as previously described in FIG. 3. The backsheet 120 can be formed with a predetermined color, e.g., inks, dyes, distortion printing, colored layers, and/or solid-colored materials, so as to conceal the solar cells 210 disposed under the frontsheet 130. Color matching between the flex s-module backsheet 120 and the molded panel 191 can be achieved by selecting resin and backsheet colors such that ΔE is less than about 2.

The backside of the panel may have indentations 317a from mechanical retention elements, such as the spring-loaded pins 317 shown in FIG. 4A. Nevertheless, the surfaces of the molded panel 191 and flex s-module 100 have a seamless, flush texture 192 and the resulting dashboard assembly 190 may serve as a freestanding panel of a vehicle.

In this embodiment, the dashboard surface has characteristics of: (i) surface texture, (ii) solar cells 210 curved in one dimension, and (iii) color matching of the solar flex s-module 100 with the molded panel 191 so as to conceal the solar cells therein or otherwise produce an aesthetic appearance. Alternatively, one or a subset of these three aspects (i)-(iii) may be selected to be combined in the dashboard assembly 190. In one example, the dashboard is substantially flat and has a texture 192 with no added color. In another example, the dashboard 190 has a printed design and the solar cells 210 and molded panel 191 are curved in one dimension. Thus, any single or combination of multiple aspects are contemplated in this disclosure.

The embodiment of FIGS. 4A-4B requires only one insert injection molding operation applied to the backside of the panel. In general, the following embodiments may be categorized by the number of insert injections (one or two) and to which side of the flex s-module they are applied (frontside/solar-facing or backside/panel-facing). The various combinations of injections and sides produce slightly different embodiments, any of which may comprise one or more inventive aspects as disclosed herein and all of which meet the requirements and provide the functionality of the panel to which they are directed. Advantages of the single-shot approach include simplicity, reduced cycle time, reduced material usage, and lower cost. Advantages of the double-shot approach include full module encapsulation, additional flexibility in the choice of injected polymers, and additional mold insert alignment and retention methods.

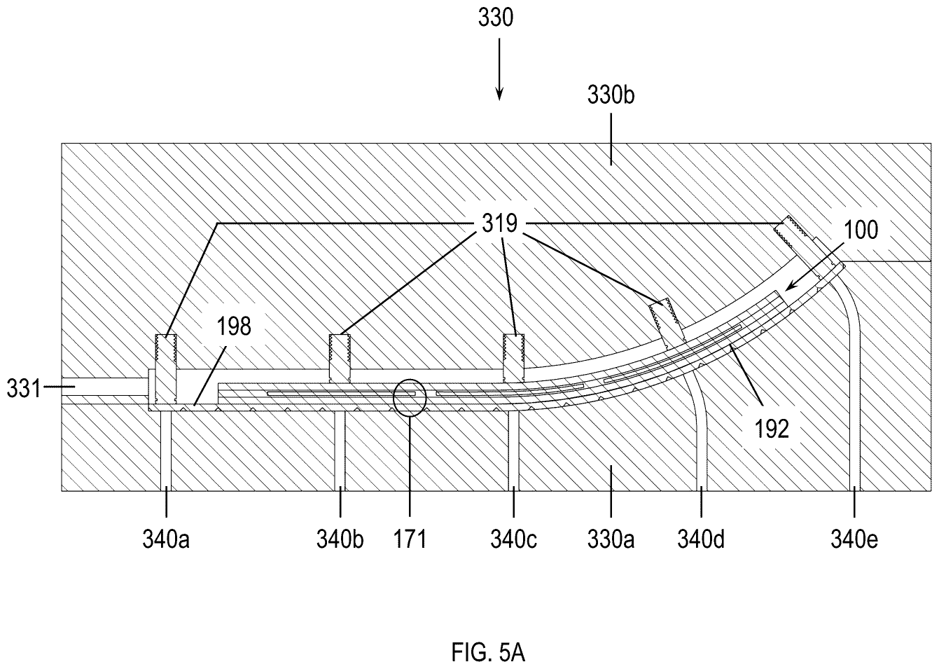

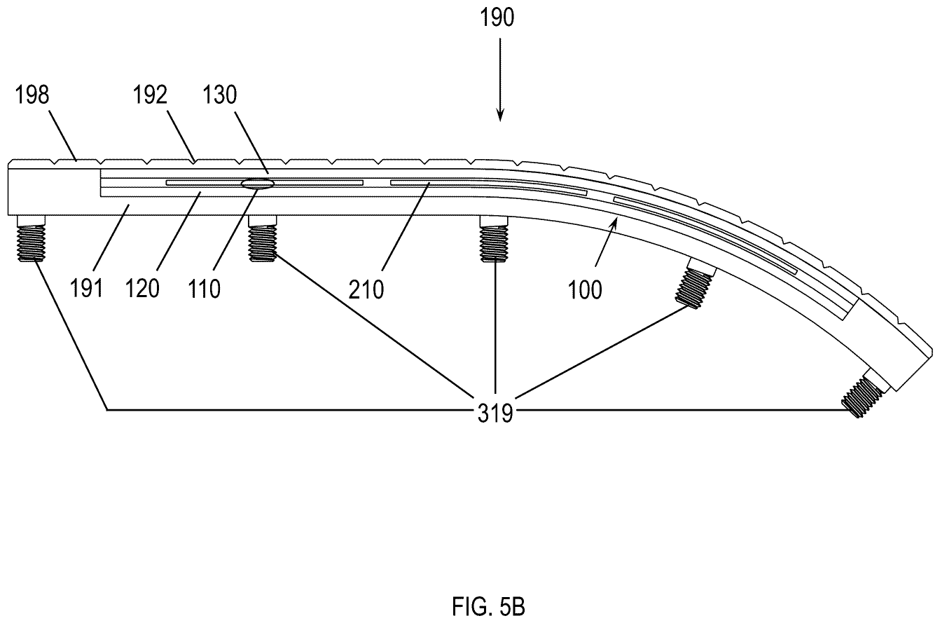

Another embodiment, illustrated in FIG. 5A, discloses a single-injection, backside only method for forming a module/cap subassembly 171 with a smooth, flex s-module 100 bonded or adhered to a textured, flexible cap sheet 198. The cap sheet 198 has the dimensions of the dashboard, is optically transparent and comprises the desired surface texture 192 of the panel. Alternatively, the module/backsheet subassembly 171 may be pre-formed into the shape of the dashboard by methods known in the art, such as thermoforming or pressure forming with the subassembly 171 retaining the dashboard shape after pre-forming. Whether flat or preformed, the subassembly 171 is then inserted into a mold 330, where it is retained by gravity and/or an interference fit. The shape of the mold 330 positively locates and maintains the position of the subassembly 171 before and during the injection process. Alternatively, or in addition, a vacuum applied to holes 340a-340e in the A-side 330a may be used to secure the subassembly 171. Alternatively, or in addition, other mechanical elements may be used to retain the flex s-module 100, as previously described. In particular, threaded bolts or dowels 319 may be inserted into the B-side of the mold and press the subassembly 171 into the A-side upon closure of the mold. Such sacrificial retention elements 319 become embedded in and part of the dashboard assembly 190. In an alternative method, the preforming may be performed in conjunction with the molding operation wherein the flexible backsheet/module subassembly 171 is retained on a frame which couples to the vacuum-enabled mold. The mold may be heated and/or pre-heated for the injection process. Just prior to injection, the heated subassembly 171 is pulled into the shape of the mold by the vacuum. In the injection process, an opaque polymer is heated, pressurized and injected into the mold cavity through the runner 331 whereby it takes the shape of the dashboard 190. Alternative runner locations may be selected, and injection aids added as necessary to facilitate the molding operation.

Referring to FIG. 5B, the dashboard assembly 190 resulting from the backside only molding operation of FIG. 5A is shown. The injected plastic forms a molded panel 191 that bonds to the cap sheet 198 and seals the edges of the flex s-module 100. The backsheet 120 is colored so as to match the molded panel 191 materials and conceal the solar cells 210. The threaded bolts or dowels 319 have become embedded in the resin and may be further used as locating and/or fastening elements of the molded panel assembly 190. The surface of the dashboard assembly 190 has a seamless, flush texture 192. The resulting assembly 190 may serve as a freestanding panel of a vehicle.

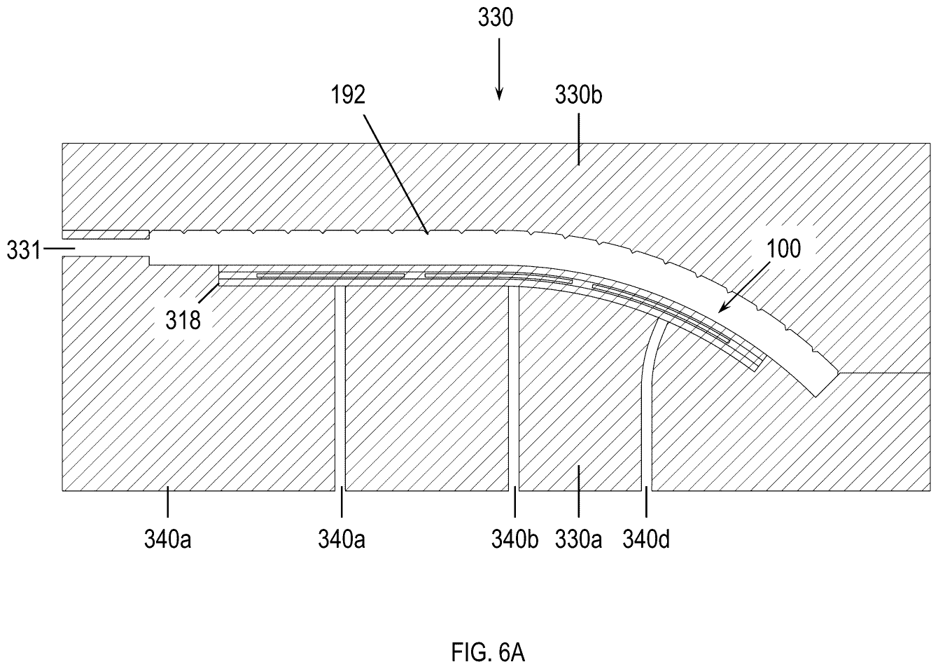

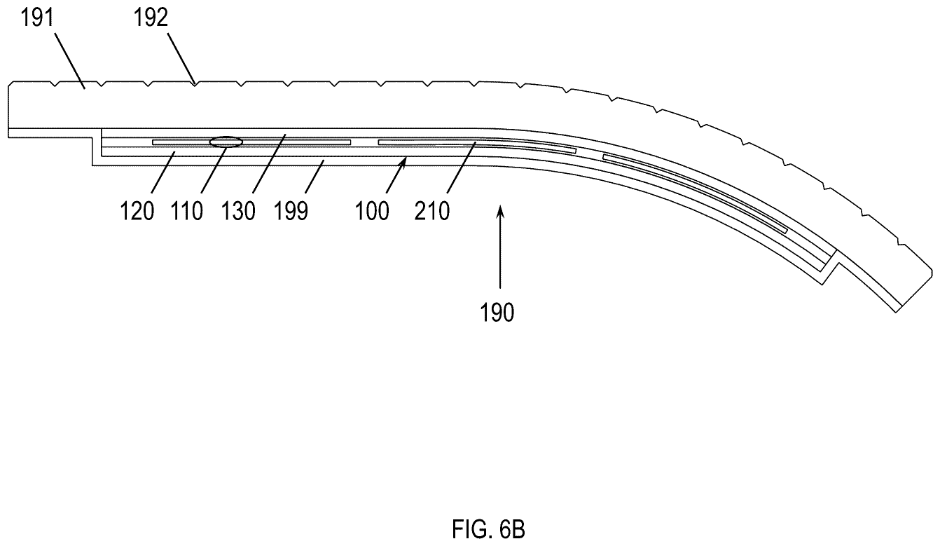

In yet another embodiment, FIG. 6A exhibits a single-injection, frontside only method for forming the dashboard assembly 190 using an optically clear resin. Also, texture 192 is provided by the mold B-side 330b. In this method, a smooth, flex s-module 100 is placed in a recess 318 disposed in the A-side 330a which positively locates and maintains the position of the flex s-module 100 with respect to the mold 330 both before and during the injection process. Alternatively, or in addition, a vacuum applied to holes 340a-340c in the A-side 330a may be used to secure the flex s-module 100 in the mold recess. In the injection process, the resin is heated, pressurized and injected into the mold cavity through the runner 331. Alternative runner and/or gate locations may be selected, and injection aids added, as necessary.

FIG. 6B illustrates the dashboard assembly 190 resulting from the molding operation of FIG. 6A. The injected resin forms a molded panel 191 that bonds to the frontsheet 130 of the flex s-module 100. Due to the mold recess 318, the edges of the flex s-module 100 are left exposed. In order to protect the flex s-module 100 perimeter and/or add color to the panel, a second backsheet 199 may be adhered to the back of the dashboard assembly 190. The resulting dashboard assembly 190 may serve as a freestanding panel of a vehicle.

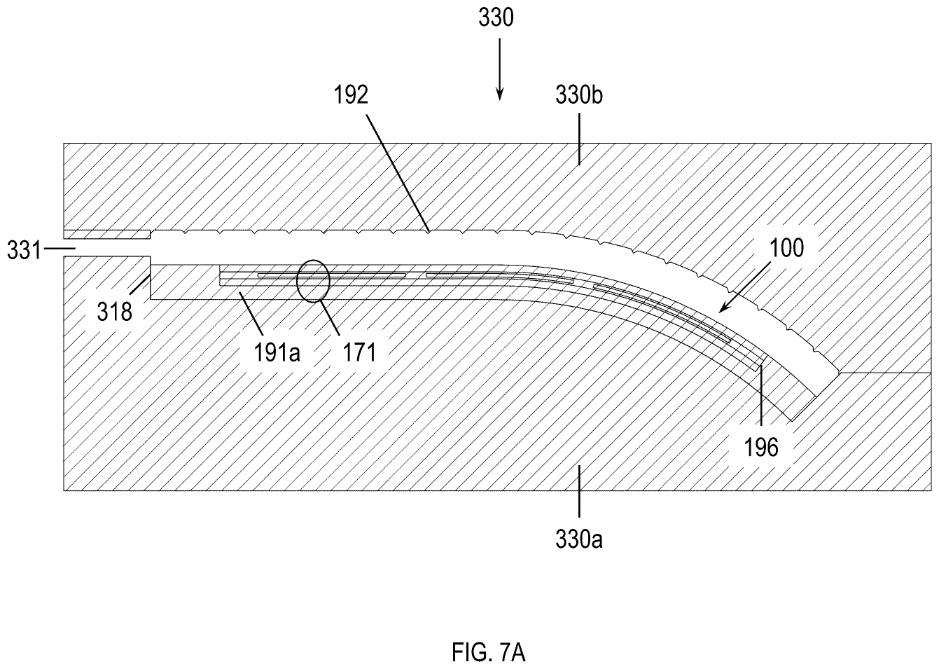

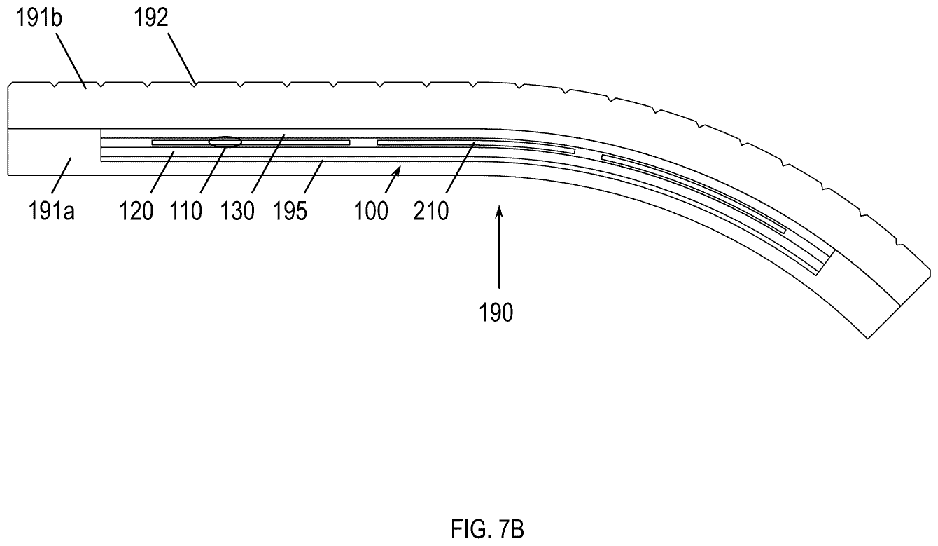

As illustrated in FIG. 7A, an alternative embodiment of a single-injection, frontside only method for forming the dashboard assembly 190 is disclosed. In this method, a smooth, flex s-module 100 is placed in a recess 196 disposed in a separately molded sub-panel 191a with the shape of the dashboard to form a subassembly 171. An adhesive may be used to bond the flex s-module 100 to the sub-panel 191a. This subassembly 171 is then inserted into a mold 330, where it is retained by gravity and/or an interference fit. The mold B-side 330b includes the desired surface texture 192 of the dashboard. An optically clear resin is injected into the mold 330 cavity through the runner 331, where it bonds to the substrate/module subassembly 171 and encapsulates the module 100.

Referring to FIG. 7B, the dashboard assembly 190 resulting from the molding operation of FIG. 7A is shown. The injected resin forms a second sub-panel 191b bonded to the first sub-panel 191a and flex s-module 100. The resulting dashboard assembly 190 may serve as a freestanding panel of a vehicle. While this approach uses a separate molded component 191a, only a single insert molding step is required and is therefore categorized as a single-injection method herein.

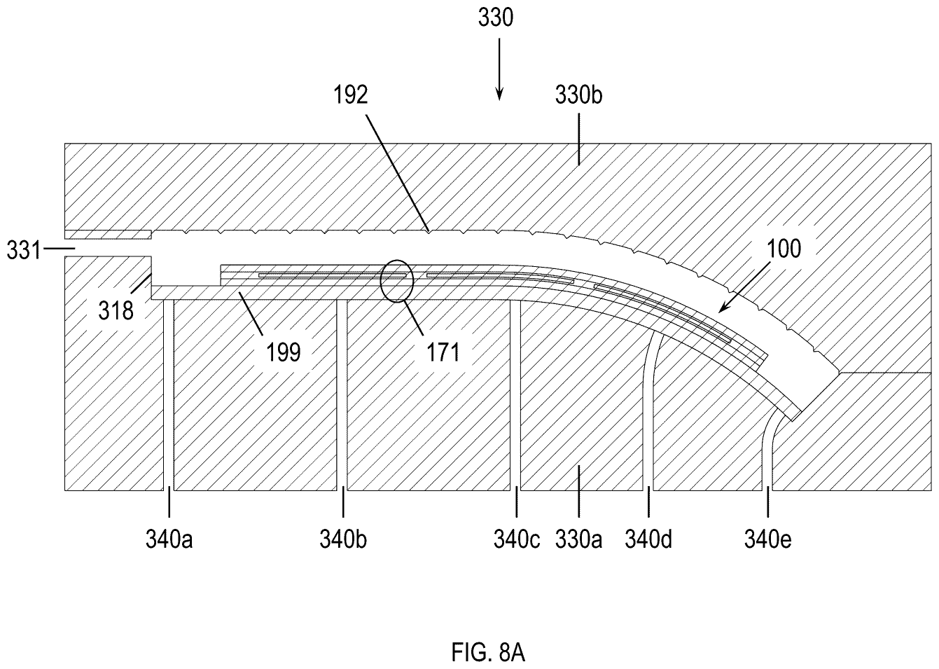

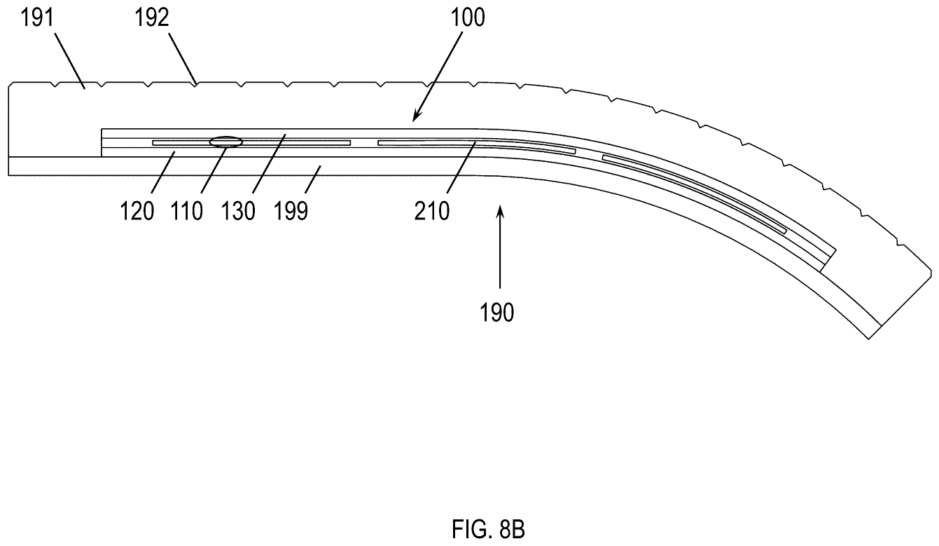

As illustrated in FIG. 8A, an alternative, single-injection, frontside only method for forming the dashboard assembly 190 is disclosed. In this approach, a flex s-module 100 is bonded or adhered to an extended secondary backsheet 199 to form a flat module/backsheet subassembly 171. The secondary backsheet 199 has the dimensions of the dashboard, is optically opaque and may comprise a desired surface color or decorative pattern of the panel. The secondary backsheet 199 may be flexible, in which case the injection molded dashboard may have simple curvature. If complex curvature is desired, the relief cuts may be made in the secondary backsheet to prevent wrinkling around the complex geometries of the mold.

Alternatively, the module/backsheet subassembly 171 may be preformed into the shape of the dashboard by methods known in the art, such as thermoforming or pressure forming with the subassembly 171 retaining the dashboard shape after pre-forming. Whether flat or preformed, the subassembly 171 is then inserted into a mold 330, where it is retained by gravity and/or an interference fit. Alternatively, or in addition, a vacuum applied to holes 340a-e in the A-side 330a may be used to secure the subassembly 171. In an alternative method, the preforming may be performed in conjunction with the molding operation wherein the flexible backsheet/module subassembly is retained on a frame which couples to the heated, vacuum-enabled mold. Just prior to injection, the heated subassembly 171 is pulled into the shape of the mold by the vacuum. The mold B-side 330b includes the desired surface texture 192 of the dashboard. An optically clear resin is injected into the mold cavity through the runner 331, where it bonds to the substrate/module subassembly 171 and encapsulates the module 100.

Referring to FIG. 8B, the dashboard assembly 190 resulting from the molding operation of FIG. 8A is shown. The injected plastic forms a sub-panel 191 that bonds to the secondary backsheet 199 and flex s-module 100 and seals the edges of the flex s-module 100. The backsheet 120 may be colored so as to match the sub-panel 191 materials and conceal the solar cells 210. The surface of the dashboard assembly 190 has a seamless, flush texture 192. The resulting dashboard assembly 190 may serve as a freestanding panel of a vehicle.

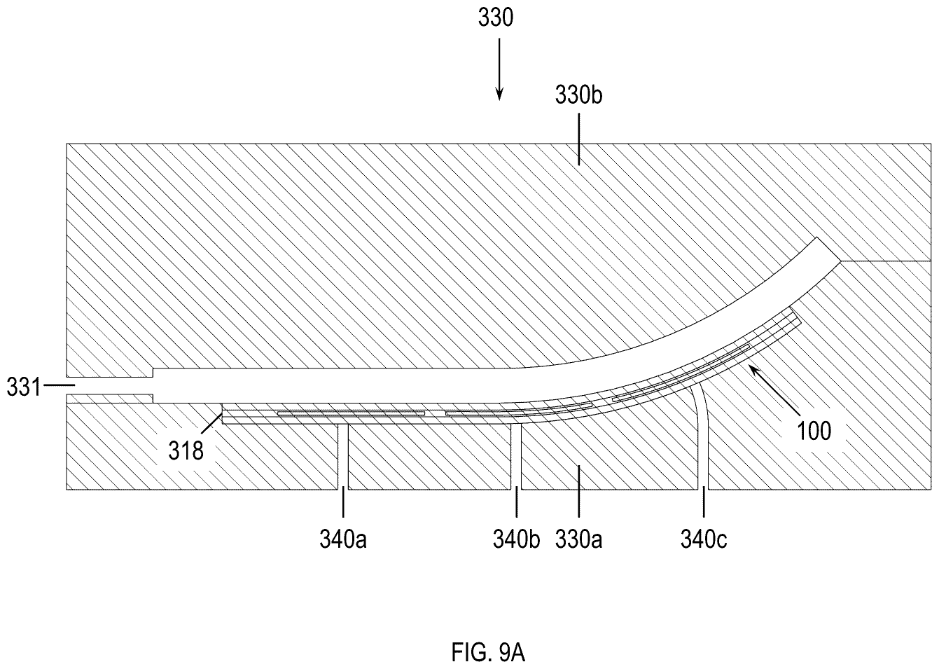

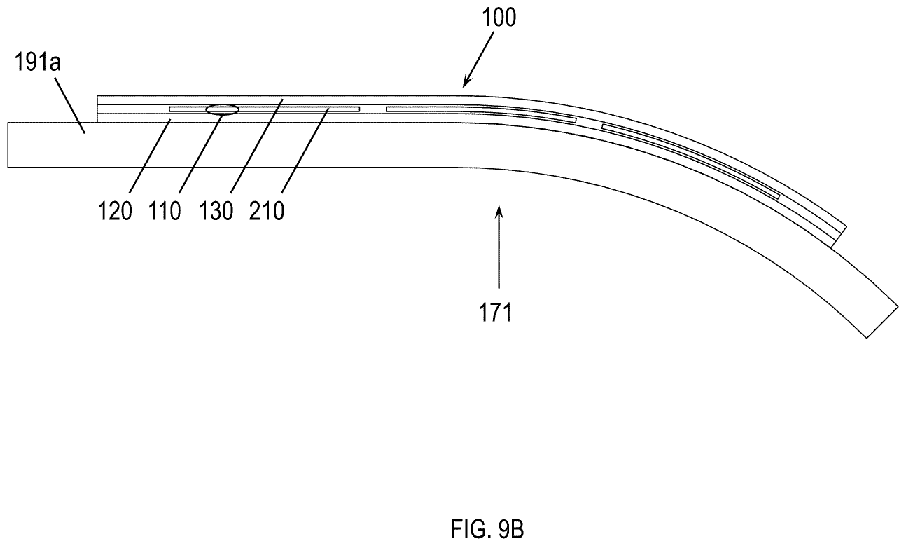

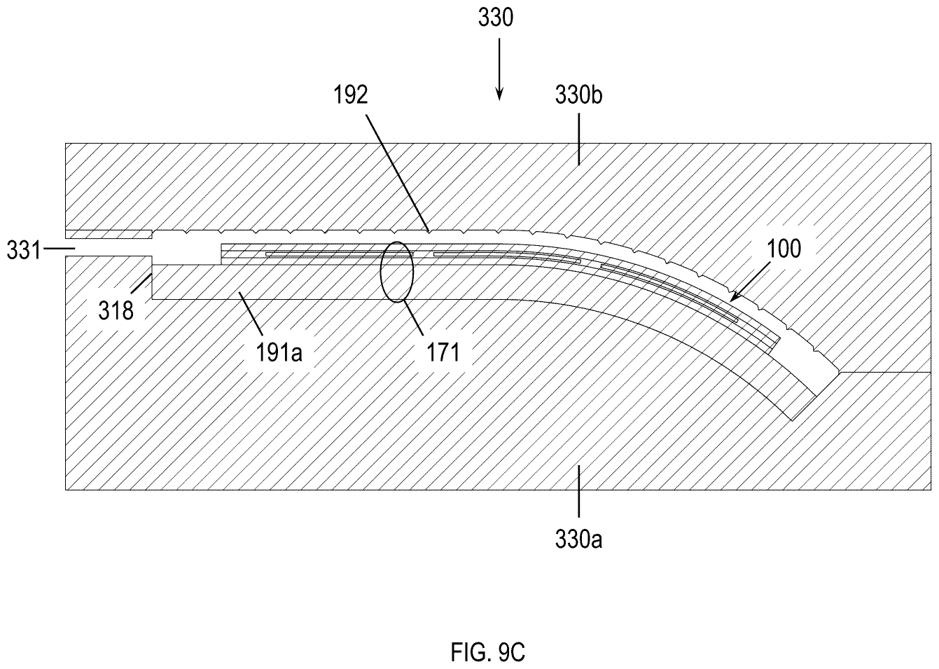

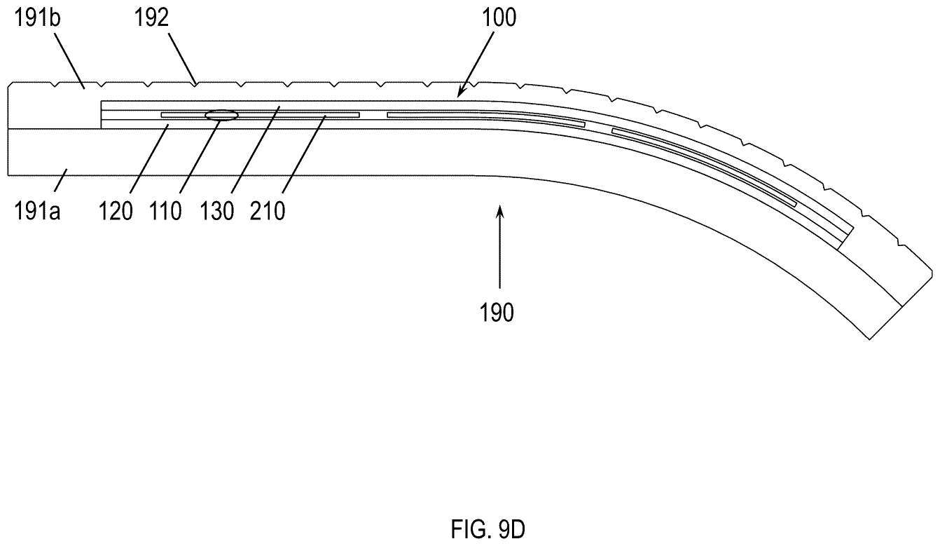

FIGS. 9A-9D illustrate the process steps for an embodiment of a double-injection method for forming the dashboard assembly 190 wherein a first, backside injection is followed by a second, frontside injection. In this method, a smooth, flex s-module 100 is inserted into a recess 318 disposed in the A-side 330a of the mold which positively locates and retains the flex s-module 100 both before and during the injection process. Alternatively, or in addition, a vacuum applied to holes 340a-340c in the A-side 330a may be used to secure the flex s-module 100 in the mold recess 318. An opaque polymer is injected into the mold 330 through the runner 331 and takes the shape of the dashboard.

Referring to FIG. 9B, the subassembly 171 resulting from the molding operation of FIG. 9A is shown. The injected resin forms a sub-panel 191a that bonds to the backsheet 120 of the flex s-module 100. Due to the mold recess 318, the edges of the flex s-module 100 are left exposed. In order to protect the flex s-module 100 perimeter and/or add texture to the panel, a second insert molding operation is necessary.

FIG. 9C illustrates the method of the second, frontside injection. In this step, the subassembly 171 is inserted into the A-side 330a of the mold where it is positively located and retained by gravity and/or an interference fit. The mold B-side 330b includes the desired surface texture 192 of the dashboard. An optically clear polymer is injected into the mold cavity through the runner 331 where it conforms to the shape of the dashboard 190.

FIG. 9D displays the dashboard assembly 190 resulting from the molding operation of FIG. 9C. The injected resin forms a second sub-panel 191b that bonds to the first subpanel 191a and flex s-module 100. The frontside subpanel 191b encapsulates the module 100 and adds texture to the panel 190. The module backsheet 120 and backside sub-panel 191a may have colors selected to achieve a combined visual effect, such as concealing the solar cells 210. The resulting dashboard assembly 190 may serve as a freestanding panel of a vehicle.

FIGS. 10A-10D illustrate the process steps for an embodiment of a double-injection method for forming the dashboard assembly 190 wherein a first, frontside injection is followed by a second, backside injection. In this method, a smooth, flex s-module 100 is inserted into a recess 318 disposed in the A-side 330a of the mold which positively locates and retains the flex s-module 100 both before and during the injection process. Alternatively, or in addition, a vacuum applied to holes 340a, 340b, and 340c in the A-side 330a may be used to secure the flex s-module 100 in the mold recess 318. The mold B-side 330b includes the desired surface texture 192 of the dashboard. A transparent polymer is injected into the mold 330 through the runner 331 and takes the shape of the dashboard, including any surface texture 192.

FIG. 10B shows the subassembly 171 resulting from the molding operation of FIG. 10A. The injected resin forms a sub-panel 191a that bonds to the frontsheet 130 of the flex s-module 100. Due to the mold recess 318, the edges of the flex s-module 100 are left exposed. In order to protect the flex s-module 100 perimeter and/or add color to the panel, a second insert molding operation is necessary.

FIG. 100 illustrates the method of the second, backside injection. In this step, the subassembly 171 is inserted into the A-side 330a of the mold which positively locates it and where it is retained by gravity and/or an interference fit. An opaque polymer is injected into the mold cavity through the runner 331 and conforms to the shape of the dashboard 190.

FIG. 10D illustrates the dashboard assembly 190 resulting from the molding operation of FIG. 100. The injected resin forms a second sub-panel 191b that bonds to the first subpanel 191a and flex s-module 100. The backside subpanel 191b encapsulates the flex s-module 100 and/or adds color to the panel. The module backsheet 120 and backside sub-panel 191b may have colors selected to achieve a combined visual effect, such as concealing the solar cells 210. The resulting dashboard assembly 190 may serve as a freestanding panel of a vehicle.

Applications of the aforementioned embodiments are not necessarily limited to vehicle or dashboard applications. For example, one or more of the embodiments may be directed to the rear window subpanel of a vehicle. Other exemplary applications include, but are not limited to, architectural panels exposed to light for interior use, vehicle panels, marine panels, aeronautical, spacecraft, and other panel applications

The previous description of the disclosed embodiments is provided to enable any person skilled in the art to make or use the invention. Various modifications to these embodiments will be readily apparent to those skilled in the art, and the generic principles defined herein can be applied to other embodiments without departing from the spirit or scope of the invention. It is therefore desired that the present embodiments be considered in all respects as illustrative and not restrictive, reference being made to the appended claims as well as the foregoing descriptions to indicate the scope of the invention.

What is claimed is:

1. A solar panel comprising:
a flexible solar module comprising:
a flexible substrate forming a back side;
a flexible superstrate forming a front side;
a core disposed therebetween, said core comprising a solar cell array including at least one solar cell, said solar cell array being encapsulated by one or more encapsulant layers;
a substrate and/or superstrate molded over said flexible solar module using an insert mold;
wherein in said at least one solar cell of said solar cell array is curved.

2. The solar panel of claim 1 wherein said overmolded superstrate includes a surface texture.

3. The solar panel of claim 1 wherein said overmolded substrate is color matched to said solar cells to within a ΔE of no greater than about 2.

4. The solar panel of claim 1 wherein the flexible superstrate and mold have a matching surface texture.

5. The solar panel of claim 4 wherein said matching surface texture may be used to align the flexible solar module to the mold and/or retain it within the mold.

6. The solar panel according to claim 1, wherein said overmolded superstrate is bonded to the front side of said flexible solar module and further comprising a secondary protective layer bonded to the back side of said flexible solar module.

7. The solar panel according to claim 1, wherein said overmolded substrate further comprises overmolded mechanical alignment pins and/or fasteners.

8. A solar panel comprising:
a flexible solar module comprising:
a flexible substrate forming a back side;
a flexible superstrate forming a front side;
a core disposed therebetween, said core comprising a solar cell array including at least one solar cell, said solar cell array being encapsulated by one or more encapsulant layers;
a flexible cap sheet bonded to and extending beyond the front side of said flexible solar module forming a flexible solar subassembly;
a substrate molded over said flexible solar subassembly using an insert mold;
wherein in said at least one solar cell of said solar cell array is curved.

9. The solar panel of claim 8 wherein said flexible cap sheet comprises a surface texture.

10. A method of manufacturing a solar panel or solar subassembly comprising the steps of:
disposing a flexible solar module in one side of an insert mold wherein it is retained;
overmolding said flexible solar module on one side.

11. The method of claim 10 wherein the flexible solar module is retained by one or more methods selected from the group consisting of: interference from a recess, a vacuum applied through one or more vacuum holes, and mechanically applied pressure.

12. The method of claim 11 wherein pressure is applied by one or more mechanical elements selected from the group consisting of: spring loaded pins, pins, dowels and threaded nuts or bolts.

13. The method of claim 10 comprising the additional steps of
disposing said solar subassembly in an insert mold where it is retained;
overmolding said solar subassembly on a side opposite said one side.

14. The method of claim 13 wherein the solar subassembly is retained by one or more methods selected from the group consisting of: interference from the mold, a vacuum applied through one or more vacuum holes, and pins and/or threaded bolts molded into said solar subassembly.
